(19) United States
(12) Patent Application Publication
(10) Pub. No.: US 2013/0282317 A1
(43) Pub. Date: Oct. 24, 2013

(54) METHOD OF CONTROLLING FAULT CURRENT IN SYSTEM FOR MONITORING AND CONTROLLING POWER SYSTEM

(71) Applicant: LSIS CO., LTD, Anyang-si (KR)

(72) Inventors: Yoon Sung CHO, Gyeonggi-do (KR); Young In KIM, Seoul (KR)

(73) Assignee: Lsis Co., Ltd, Anyang-si (KR)

(21) Appl. No.: 13/856,388

(22) Filed: Apr. 3, 2013

(30) Foreign Application Priority Data
Apr. 23, 2012 (KR) 10-2012-0041880

(51) Int. Cl. G01R 31/333

(52) U.S. Cl. CPC G01R 31/333
USPC 702/64

(57) ABSTRACT

Disclosed is a system for acquiring and controlling information of power energy production, power transmission, and power consumption by storing information of circuit breakers, switches, power generators, power transmission lines, and transformers in the database, and a method of controlling the same. The method includes acquiring data from a remote control system, comparing the acquired data with data that are previously stored in a database, calculating an estimation value of data that are not acquired according to a comparison result, and performing fault current analysis or contingency analysis according to the calculated estimation value to calculate a rated capacity of a circuit breaker.

### CROSS-REFERENCE TO RELATED APPLICATION

Pursuant to 35 U.S.C. §119(a), this application claims the benefit of earlier filing date and right of priority to Korean Application No. 10-2012-0041880, filed on Apr. 23, 2012, the contents of which is incorporated by reference herein in its entirety.

### BACKGROUND

The present embodiment relates to a system for acquiring and controlling information of power energy production, power transmission, and power consumption by storing information of circuit breakers, switches, power generators, power transmission lines, and transformers in the database, and a method of controlling the same.

In order to construct a data acquisition and control system (e.g., EMS, SCADA, AMI), a remote control unit realized in hardware, a database, an application for analysis, and system security must be developed. Particularly, in order to ensure the stability and the economical efficiency of a national power system, the EMS, in which an advanced IT technology is integrated with a high-level power system application technology, is essentially required when operating a power system for monitoring and controlling a power system handling ten million kW or more of power.

In addition, there is limitation when broadening a power system, connecting to large-scale power generation facilities, and operating the power system in real-time under extreme weather through the operating and the reviewing of a national power transmission network based on a conventional scheme. Accordingly, the above limitation must be overcome, and the system integrity based on the operating state of a rapidly-changing power system must be evaluated, so that the countermeasures against the weak part can be established.

FIG. 1 is a flowchart showing the analyzing of fault current in a data acquisition and control system.

Referring to FIG. 1, the data acquisition system acquires real-time analog and digital data from a supervisor control and data acquisition (SCADA) system and remote terminal units (RTU) installed in a power station and a substation, and stores the acquired data in a real-time database (step S105).

The data stored in the real-time database is transferred to a system analysis database, so that physical node-based information for analysis is converted into electrical-motion-based information for the purpose of topology analysis (step S110).

The state of the data, which have been subject to the topology analysis, is estimated in order to correct incorrect data resulting from the errors of an RTU for in-situ data acquisition, a modem, and communication equipment, and provide the estimated value of a material that is not acquired yet (step S115).

On the assumption that a balance accident and an unbalance accident occurs in a predetermined system, voltage and current expected on a fault point, and a bus or a line of the fault point are calculated (step S 120), and the rated capacity of a circuit breaker is calculated (step S 125).

It is determined if the calculated rated capacity of the circuit breaker exceeds preset capacity (step S130). An alarm function is performed according to the determination result (step S135).

As described above, the data acquisition and control system installed in a conventional system calculates the rated capacity of the circuit breaker by analyzing the fault current, and performs the alarm function depending on the rated capacity of the circuit breaker that is calculated.

However, the conventional system cannot calculate the rated capacity of the circuit breaker when facilities are broken away or events according to the operations of the circuit breaker occurs. In addition, since the conventional system cannot calculate the rated capacity by taking into consideration various faults, the conventional system cannot propose recommendations to solve faults when the faults occur.

### SUMMARY

The embodiment provides a method of reducing fault current in a system for monitoring and controlling a power system, capable of calculating the rated capacity of a circuit breaker by taking into consideration various faults.

The embodiment provides a method of reducing fault current in a system for monitoring and controlling a power system, capable of easily obtaining causes of faults and schemes of solving the faults by taking into consideration various faults.

According to the embodiment, there is provided a method of controlling fault current including acquiring data from a remote control system, comparing the acquired data with data that are previously stored in a database, calculating an estimation value of data that are not acquired according to a comparison result, and performing fault current analysis or contingency analysis according to the calculated estimation value to calculate a rated capacity of a circuit breaker.

According to the embodiment, there is provided a method of controlling fault current. The method includes acquiring data from a remote control system and calculating a rated capacity of a circuit breaker based on the acquired data, selecting a contingency having a priority from a preset list of contingencies based on the calculated rated capacity, searching for facilities serving as a cause of the selected contingency, adjusting parameter values for the searched facilities, performing topology analysis and power flow analysis of the facilities subject to the adjustment of the parameter values, and selecting fault current according to the topology analysis and the power flow analysis.

### BRIEF DESCRIPTION OF THE DRAWINGS

FIG. 1 is a flowchart showing the analyzing of fault current in a data acquisition and control system according to the related art.

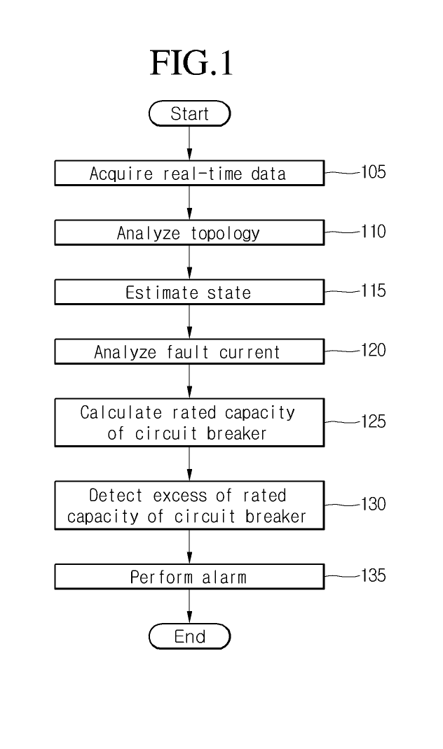

FIG. 2 is a flowchart showing an operation of calculating the rated capacity of a circuit breaker according to the embodiment.

FIG. 3 is a flowchart used to select a recommendation to reduce fault current according to the embodiment.

### DETAILED DESCRIPTION OF THE EMBODIMENTS

Terms and words used in the specification and the claims shall not be interpreted as commonly-used dictionary meanings, but shall be interpreted as to be relevant to the technical scope of the invention based on the fact that the inventor may property define the concept of the terms to explain the invention in best ways.

Therefore, the embodiments and the configurations depicted in the drawings are illustrative purposes only and do not represent all technical scopes of the embodiments, so it should be understood that various equivalents and modifications may exist at the time of filing this application.

Hereinafter, the embodiment will be described in detail with reference to accompanying drawings.

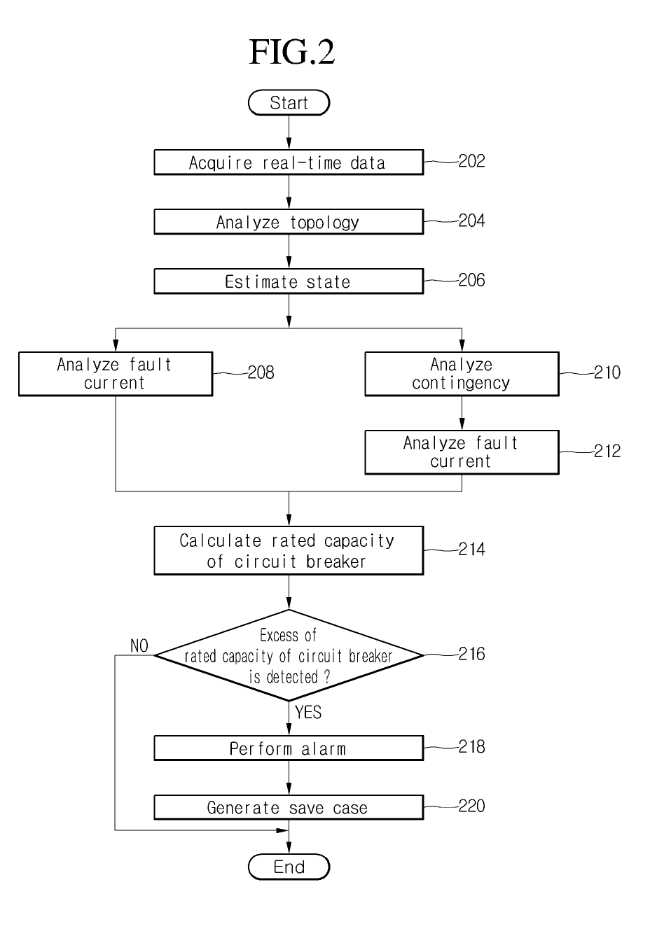

FIG. 2 is a flowchart showing the calculating of a rated capacity of a circuit breaker according to the embodiment.

Referring to FIG. 2, a data acquisition system acquires analogue and digital data from an upper level system such as an SCADA, an RTU, or an AMI, and stores the acquired data into a database (step S202).

The data acquisition system may form the information of a physical system based on the acquired data and data that has been previously stored in the database (step S204).

The data acquisition system may correct data, which has been incorrectly measured due to the errors of equipment connected to the upper level system, and calculate an estimation value of data, which are not acquired yet, by referring to the acquired data (step S206).

The data acquisition system performs fault current analysis according to the estimation value of the data which are not acquired yet (step S208).

The data acquisition system may calculate the rated capacity of a circuit breaker based on the result of the fault current analysis based on the estimation value (step S214).

The data acquisition system may analyze an individual contingency in a preset list of contingencies (step S210). The data acquisition system may analyze fault current in relation to the analyzed contingency (step S212). The data acquisition system can calculate the rated capacity of the circuit breaker based on the analyzed fault current (step S214).

The data acquisition system may analyze the individual contingency by using the preset list of the contingencies (step S210).

The data acquisition system may analyze the fault current with respect to the analyzed contingency (step S212), and calculate the rated capacity of the circuit breaker according to the fault current (step S214).

The data acquisition system determines if the calculated rated capacity exceeds a reference rated capacity of a circuit breaker that is installed (step S216). If the calculated rated capacity exceeds the reference rated capacity of the installed circuit breaker, an alarm function may be performed (step S218).

The data acquisition system may store a save case for the excess of the rated capacity according to the fault current analysis when the alarm occurs (step S220).

The save case may be stored in the database. Upon the rated capacity of the circuit breaker, the save case stored in the database is read and power flow analysis is performed, and the operating value of a relay is viewed, so that the alarm may occur, or the database may be updated.

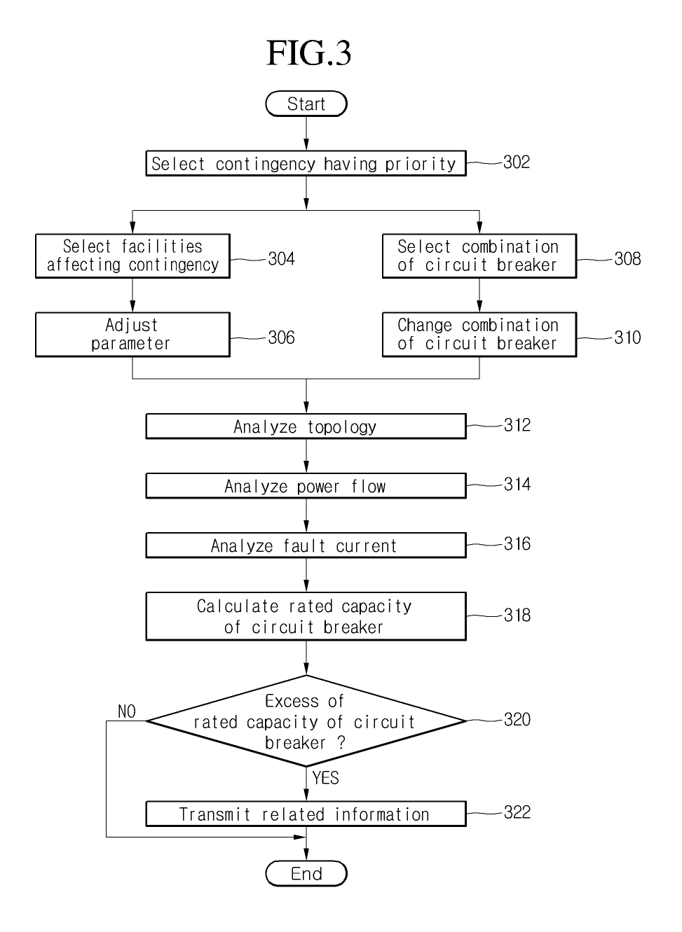

FIG. 3 is a flowchart used to select a recommendation to reduce fault current according to the embodiment.

Referring to FIG. 3, the data acquisition system may select a contingency having a priority in the list of the contingencies upon the rated capacity of the circuit breaker, which is calculated in FIG. 2 (step S302). If levels are set to contingencies in the preset list of contingencies, the contingency having the highest level may be selected.

The data acquisition system may check facilities serving as a cause of the selected contingency having the priority (step S304). The data acquisition system may adjust parameter values for the facilities having the contingency having the priority (step S306).

Meanwhile, the data acquisition system may change the combination of circuit breakers according to the selected contingency having the priority. In other words, the data acquisition system determines the type of the combination of the circuit breakers according to the selected contingency and selects a circuit breaker to be changed (step S308).

The data acquisition system changes the combination having the selected circuit breaker (step S310).

The data acquisition system performs topology analysis and power flow analysis with respect to the circuit breakers having the changed combination and the facilities having the contingency subject to the adjustment of the parameter values (steps S312 and S314).

The fault current analysis is performed according to the results of the topology analysis and the power flow analysis (step S316). The rated capacity of the circuit breaker can be calculated by analyzing the fault current (step S318).

The data acquisition system may determine if the calculated rated capacity of the circuit breaker exceeds a rated capacity of a circuit breaker which is installed (step S320). The data acquisition system may transmit the information of the calculated rated capacity and the state information of the related circuit breaker to a preset destination including a monitoring system if the calculated rated capacity exceeds the rated capacity of the installed circuit breaker (step S322).

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of controlling fault current, the method comprising:
acquiring data from a remote control system;
comparing the acquired data with data that are previously stored in a database;
calculating an estimation value of data, which are not acquired, according to a comparison result; and
performing fault current analysis or contingency analysis according to the calculated estimation value to calculate a rated capacity of a circuit breaker.

2. The method of claim 1, wherein the performing of the fault current analysis or the contingency analysis comprises:
analyzing an individual contingency based on a preset list of contingencies; and
analyzing fault current of a system with respect to the analyzed contingency.

3. The method of claim 1, further comprising:
determining if the calculated rated capacity of the circuit breaker exceeds a preset reference rated capacity of the circuit breaker; and
generating an alarm if the calculated rated capacity of the circuit breaker exceeds the preset reference rated capacity.

4. The method of claim 1, further comprising storing the calculated rated capacity of the circuit breaker and a save case of the circuit breaker in a database.

5. The method of claim 4, wherein the save case stored in the database is read and power flow analysis is performed upon the rated capacity of the circuit breaker.

6. A method of controlling fault current, the method comprising:
acquiring data from a remote control system and calculating a rated capacity of a circuit breaker based on the acquired data;
selecting a contingency having a priority from a preset list of contingencies based on the calculated rated capacity;
searching for facilities serving as a cause of the selected contingency;
adjusting parameter values for the searched facilities;
performing topology analysis and power flow analysis for the facilities subject to the adjustment of the parameter values; and
calculating fault current according to the topology analysis and the power flow analysis.

7. The method of claim 6, further comprising:
changing combination of circuit breakers of the searched facilities if the facilities serving as the cause of the contingency are searched;
performing topology analysis and power flow analysis for the circuit breakers subject to the change of the combination thereof; and
calculating the fault current according to the topology analysis and the power flow analysis.

8. The method of claim 6, further comprising:
determining if the rated capacity of the circuit breaker exceeds a preset rated capacity of the circuit breaker according to the calculated fault current; and
performing an alarm function if the calculated rated capacity of the circuit breaker is determined as exceeding the preset rated capacity of the circuit breaker based on the calculated fault current.

9. The method of claim 8, further comprising transmitting information of the calculated rated capacity and a save case of the related circuit breaker to a preset destination if the calculated rated capacity of the circuit breaker is determined as exceeding the preset rated capacity of the circuit breaker based on the calculated fault current.
